(19) United States
(12) Patent Application Publication
(10) Pub. No.: US 2007/0085131 A1
(43) Pub. Date: Apr. 19, 2007

(54) Semiconductor device

(76) Inventors: Kouji Matsuo, Yokohama-shi (JP); Ichiro Mizushima, Yokohama-shi (JP); Toshihiko Iinuma, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/543,146

(22) Filed: Oct. 5, 2006

(30) Foreign Application Priority Data
Oct. 7, 2005 (JP) 2005-294742

(51) Int. Cl. H01L 29/788

(52) U.S. Cl. 257/315

(57) ABSTRACT

A semiconductor device includes a semiconductor substrate which has a cavity and has a source region, a drain region, and a channel region above the cavity, a gate electrode which is formed on the channel region with a gate insulating film interposed between the gate electrode and the channel region, and a stress generating film which has a first portion formed on the upper surface of the cavity and which gives a strain to the channel region.

### CROSS-REFERENCE TO RELATED APPLICATIONS

This application is based upon and claims the benefit of priority from prior Japanese Patent Application No. 2005-294742, filed Oct. 7, 2005, the entire contents of which are incorporated herein by reference.

### BACKGROUND OF THE INVENTION

1. Field of the Invention

The present invention relates to a semiconductor device.

2. Description of the Related Art

Techniques that give a strain to the channel region of a MISFET to increase the channel mobility thereof are recently attracting attention. As one of such techniques, there is known a method that covers the MISFET with a silicon nitride film and gives a strain to a silicon substrate using the stress of the silicon nitride film (see F. Ootsuka, etc., IEDM Tech. Digest, P575, 2000).

In order to increase the stress, the thickness of a stress generating film such as a silicon nitride film needs to be increased. However, when the thickness of the stress generating film is increased, it becomes difficult to form a contact hole with accuracy, adversely affecting miniaturization of a semiconductor device. When the thickness of the stress generating film is reduced, a satisfactory strain cannot be given to the silicon substrate.

In general, an upper layer film such as an interlayer insulating film is formed on the stress generating film. Therefore, a stress acts between the stress generating film and upper layer film. As a result, the stress acting between the stress generating film and silicon substrate is restricted by the upper layer film, preventing a satisfactory strain from being given to the silicon substrate.

As described above, it has been impossible to give a satisfactory strain to the channel region using the stress generating film and, therefore, it has been difficult to obtain a semiconductor device excellent in performance.

### BRIEF SUMMARY OF THE INVENTION

According to an aspect of the present invention, there is provided a semiconductor device comprising: a semiconductor substrate which has a cavity and has a source region, a drain region, and a channel region above the cavity; a gate electrode which is formed on the channel region with a gate insulating film interposed between the gate electrode and the channel region; and a stress generating film which has a first portion formed on the upper surface of the cavity and which gives a strain to the channel region.

### BRIEF DESCRIPTION OF THE SEVERAL VIEWS OF THE DRAWING

FIG. 1A and FIG. 1B are views schematically showing a part of a manufacturing method of a semiconductor device according to a first embodiment of the present invention;

FIG. 2A and FIG. 2B are views schematically showing a part of a manufacturing method of the semiconductor device according to the first embodiment of the present invention;

FIG. 3A and FIG. 3B are views schematically showing a part of a manufacturing method of the semiconductor device according to the first embodiment of the present invention;

FIG. 4A, FIG. 4B and FIG. 4C are views schematically showing a part of a manufacturing method of the semiconductor device according to the first embodiment of the present invention;

FIG. 5A, FIG. 5B, and FIG. 5C are views schematically showing a part of a manufacturing method of the semiconductor device according to the first embodiment of the present invention;

FIG. 6A, FIG. 6B, and FIG. 6C are views schematically showing a part of a manufacturing method of the semiconductor device according to the first embodiment of the present invention;

FIG. 7A, FIG. 7B, and FIG. 7C are views schematically showing a part of a manufacturing method of the semiconductor device according to the first embodiment of the present invention;

FIG. 8A, FIG. 8B, and FIG. 8C are views schematically showing a part of a manufacturing method of the semiconductor device according to the first embodiment of the present invention;

FIG. 9A, FIG. 9B, and FIG. 9C are views schematically showing a part of a manufacturing method of the semiconductor device according to the first embodiment of the present invention;

FIG. 10A and FIG. 10B are views schematically showing a part of a manufacturing method of a semiconductor device according to a second embodiment of the present invention;

FIG. 11A and FIG. 11B are views schematically showing a part of a manufacturing method of the semiconductor device according to the second embodiment of the present invention;

FIG. 12A and FIG. 12B are views schematically showing a part of a manufacturing method of the semiconductor device according to the second embodiment of the present invention;

FIG. 13A and FIG. 13B are views schematically showing a part of a manufacturing method of the semiconductor device according to the second embodiment of the present invention;

FIG. 14A and FIG. 14B are views schematically showing a part of a manufacturing method of the semiconductor device according to the second embodiment of the present invention;

FIG. 15A and FIG. 15B are views schematically showing a part of a manufacturing method of a semiconductor device according to a third embodiment of the present invention;

FIG. 16A, FIG. 16B, and FIG. 16C are views schematically showing a part of a manufacturing method of the semiconductor device according to the third embodiment of the present invention;

FIG. 17A, FIG. 17B, and FIG. 17C are views schematically showing a part of a manufacturing method of the semiconductor device according to the third embodiment of the present invention;

FIG. 18A, FIG. 18B, and FIG. 18C are views schematically showing a part of a manufacturing method of the semiconductor device according to the third embodiment of the present invention; and

FIG. 19A, FIG. 19B, and FIG. 19C are views schematically showing a part of a manufacturing method of the semiconductor device according to the third embodiment of the present invention.

### DETAILED DESCRIPTION OF THE INVENTION

Embodiments of the present invention will be described below with reference to the accompanying drawings.

### FIRST EMBODIMENT

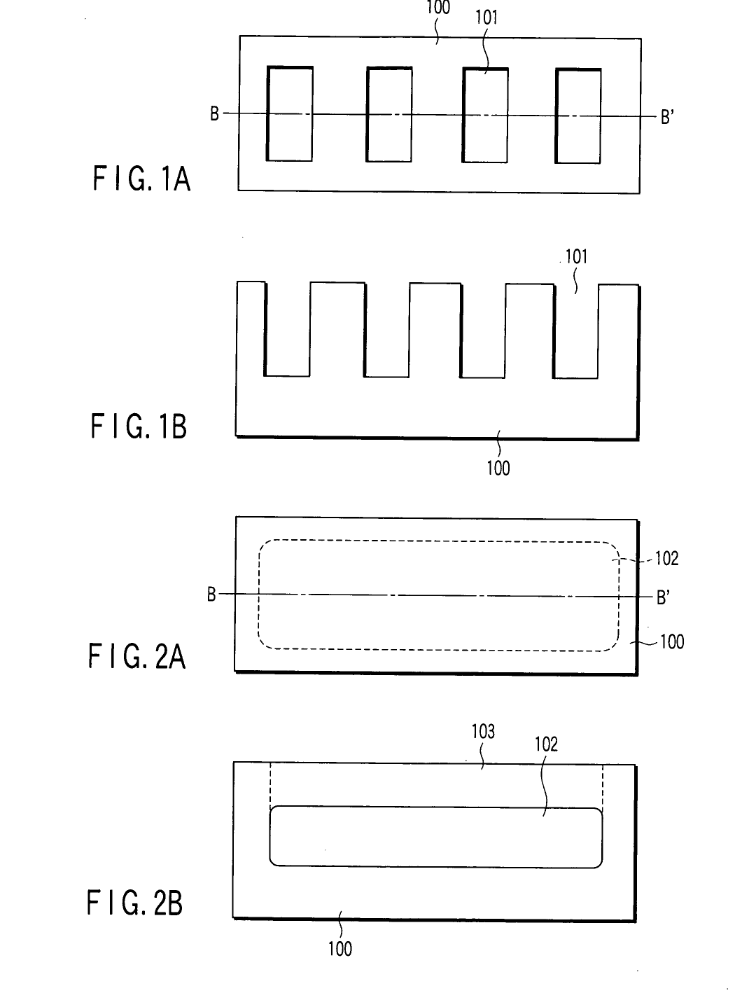

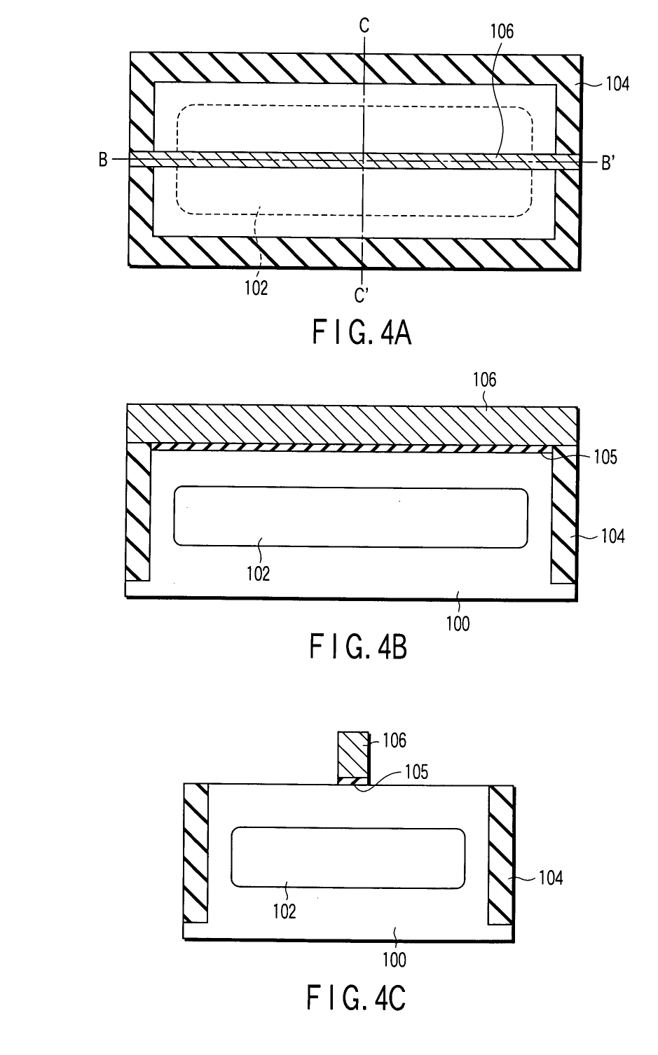

FIGS. 1A to 9A, FIGS. 1B to 9B, and FIGS. 4C to 9C are views showing a manufacturing method of a semiconductor device according to a first embodiment. FIGS. 1A to 9A are plan views, FIGS. 1B to 9B are cross-sectional views taken along B-B′ lines of FIGS. 1A to 9A respectively, and FIGS. 4C to 9C are cross-sectional views taken along C-C′ lines of FIGS. 4A to 9A respectively.

As shown in FIGS. 1A and 1B, a plurality of trenches 101 are formed in a silicon substrate (semiconductor substrate) 100.

Then, as shown in FIGS. 2A and 2B, annealing treatment is performed in non-oxidizing atmosphere (10 torr, 1000° C., 100% hydrogen atmosphere) under low pressure. As a result, the trenches 101 are deformed to form a cavity 102, resulting in formation of so-called an SON (Silicon On Nothing) region 103 on the cavity 102. Then, the surface of the silicon substrate 100 is flattened by a CMP method or the like. Note that the formation technique of the SON region 103 is described in Jpn. Pat. Appln. No. 10-115310, which can be applied to the present embodiment.

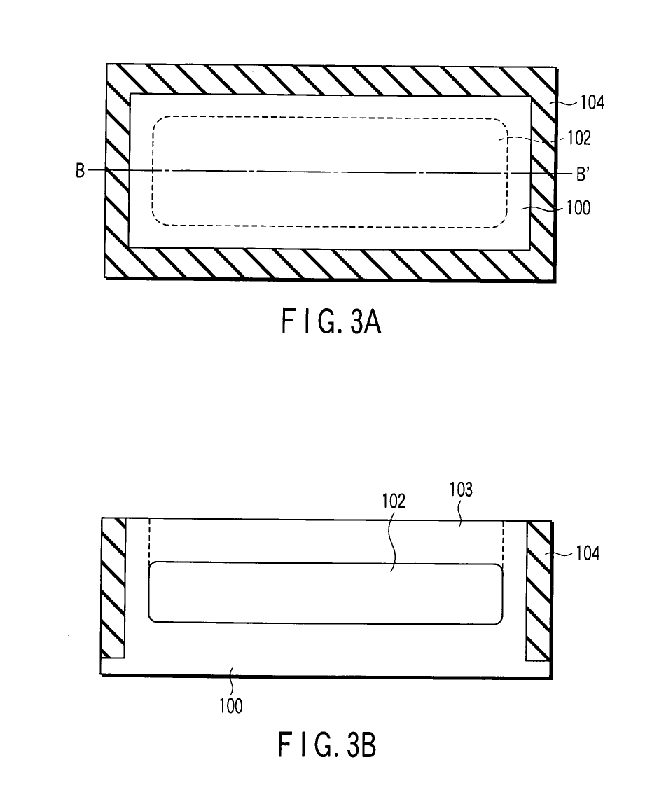

Next, as shown in FIGS. 3A and 3B, an isolation region 104 which surrounds the SON region 103 is formed. For example, a silicon oxide film (SiO₂ film) can be used as the isolation region 104.

Next, as shown in FIGS. 4A, 4B, and 4C, a gate electrode 106 is formed on the silicon substrate 100 with a gate insulating film 105 interposed therebetween. For example, a silicon oxide film and a polysilicon film can be used as the gate insulating film 105 and gate electrode 106, respectively.

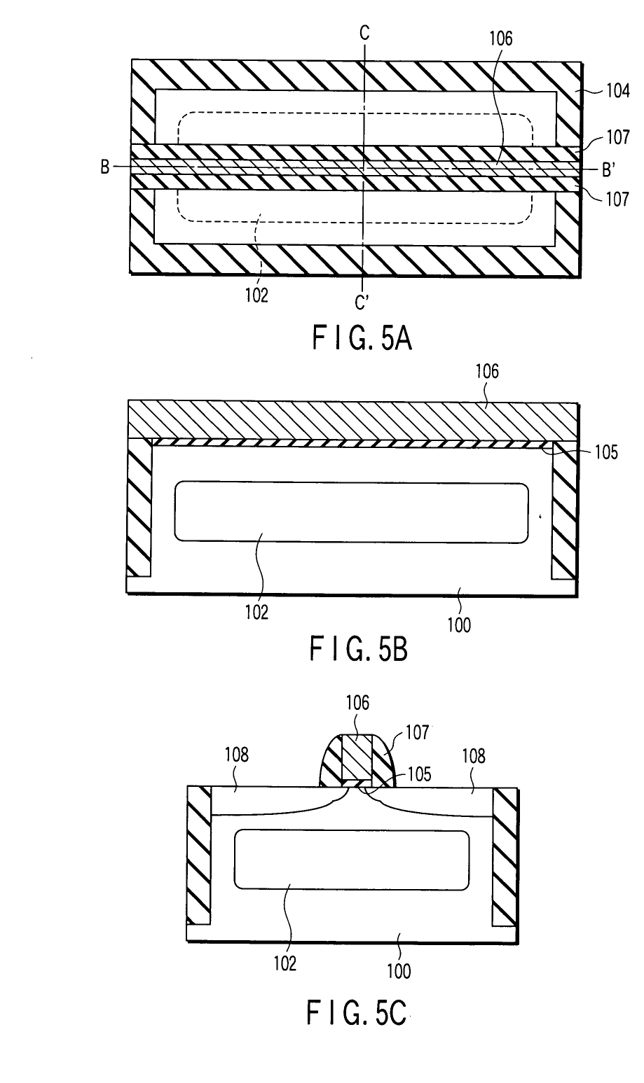

Next, as shown in FIGS. 5A, 5B, and 5C, an extension region is formed by an impurity ion implantation using the gate electrode 106 as a mask. Subsequently, a gate side wall 107 formed of a silicon nitride film (Si₃N₄ film) is formed. Further, a deep diffusion region is formed by an impurity ion implantation using the gate side wall 107 as a mask. As a result, a source/drain region 108 formed by the extension diffusion region and deep diffusion region is obtained. In the manner as described above, a MIS transistor having the gate insulating film 105, gate electrode 106, and source/drain region 108 is formed.

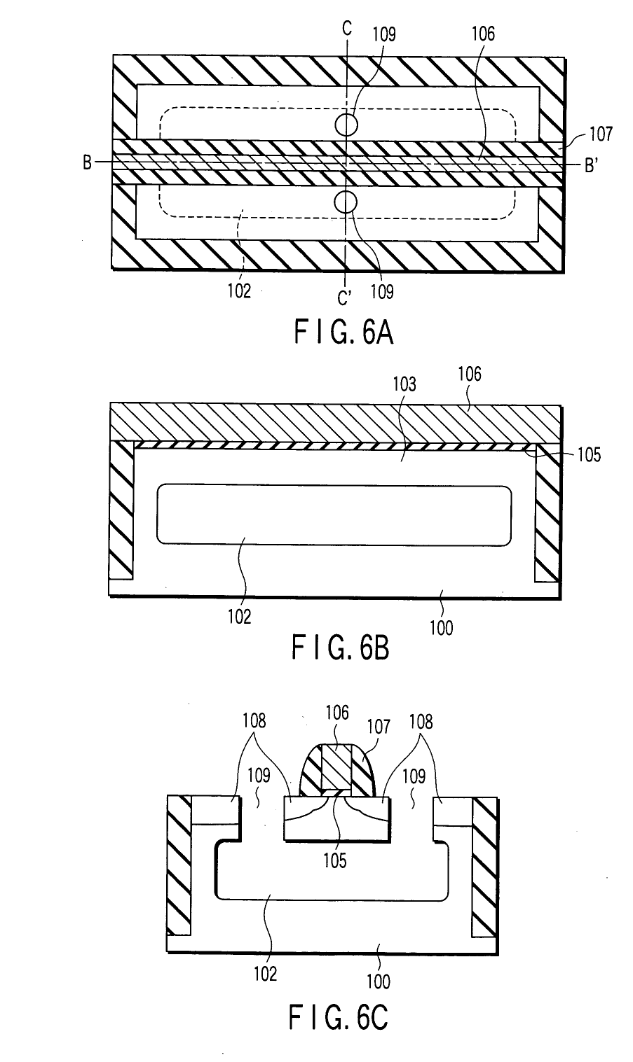

Next, as shown in FIGS. 6A, 6B, and 6C, a hole 109 which reaches the cavity 102 is formed in the SON region 103 of the silicon substrate 100. Although two holes 109 are formed in the drawings, the number of holes 109 to be formed may be one, or three or more.

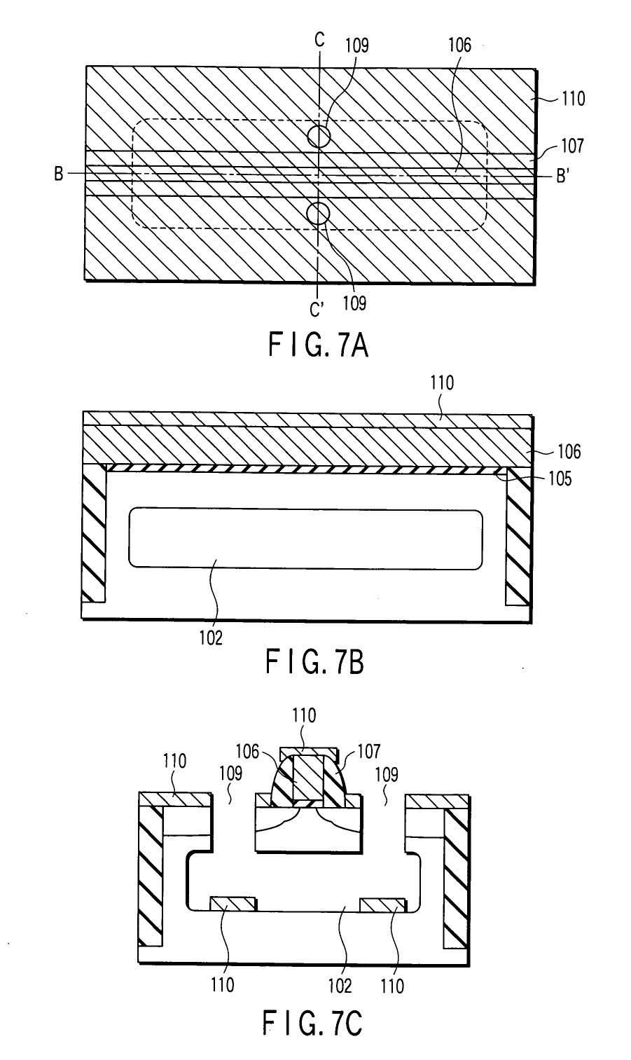

Next, as shown in FIGS. 7A, 7B, and 7C, a metal film 110 such as a nickel (Ni) film having a thickness of about 10 nm is formed on the entire surface by a sputtering process. At this time, the metal film 110 is formed also under the hole 109. It is preferable that the metal film 110 be formed by a highly anisotropic sputtering process such as a long-throw sputtering so that the metal film 110 is not thickly formed on the side surface of the hole 109.

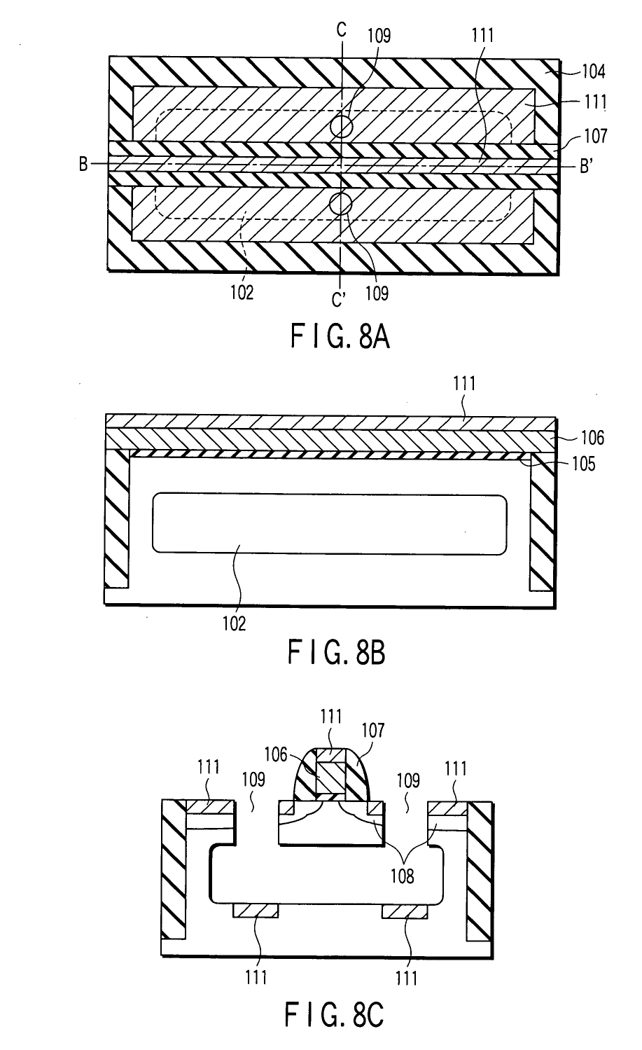

Next, as shown in FIGS. 8A, 8B, and 8C, heat treatment is performed at a temperature of about 200 to 500° C. As a result, the nickel film 110 and silicon are reacted with each other to thereby form an Ni silicide film (metal silicide film) 111. Further, a mixture of sulfuric acid and hydrogen peroxide solution is used to perform wet etching to thereby remove the unreacted nickel film 110. As a result, so-called a salicide structure in which the Ni silicide film is formed on the gate electrode 106 and source/drain region 108 is obtained. Note that, in the above process, the Ni silicide film 111 is formed also under the hole 109.

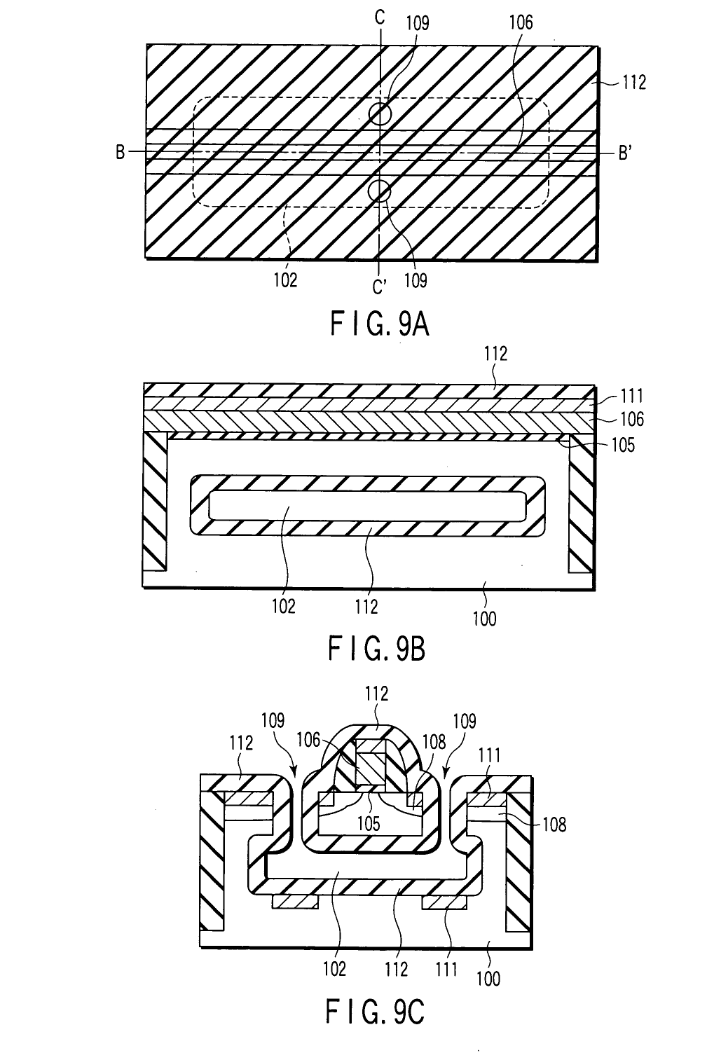

Next, as shown in FIGS. 9A, 9B, and 9C, a silicon nitride film serving as a stress generating film 112 for giving a strain to the surface of the silicon substrate 100 is formed by a low pressure CVD process. As a result, a silicon nitride film 112 is so formed as to cover the surface of the substrate on which the MIS transistor has been formed. Since the hole 109 which reaches the cavity 102 is formed in the silicon substrate 100, a source gas for the silicon nitride film 112 is supplied also to the inside of the cavity 102 through the hole 109. It follows that the silicon nitride film 112 is formed also on the entire inner surface of the cavity 102. In addition, the silicon nitride film 112 is formed also on the side surface of the hole 109.

In the manner as described above, a semiconductor device as shown in FIGS. 9A, 9B, and 9C is obtained. That is, the MIS transistor in which the source/drain region 108 and channel region have been formed above the cavity 102, and the gate electrode 106 has been formed on the channel region with the gate insulating film 105 interposed therebetween is obtained.

Although not shown in particular, formation processes of an interlayer insulating film, contacts connected respectively to the source region and drain region, and the like are performed subsequently.

As described above, in the present embodiment, the cavity 102 is previously formed inside the silicon substrate 100. Then the stress generating film (silicon nitride film) 112 is formed by a vapor deposition process such as a CVD after formation of the hole 109 which reaches the cavity 102. As a result, the stress generating film 112 can be formed on the entire inner surface of the cavity 102. Therefore, in the present embodiment, the stress generating film 112 has a portion (second portion) that covers the source/drain region 108 as well as a portion (portion (first portion) that has been formed on the upper surface of the cavity 102) that has been formed on the bottom surface of the SON region 103. Accordingly, a stress can be applied to the channel region from the upper and lower regions. It follows that it is possible to apply a satisfactory strain to the channel region without the thickness of the stress generating film 112 being increased.

Further, the cavity 102 is formed under the first portion (portion that has been formed on the upper surface of the cavity 102) of the stress generating film 112, preventing a stress from directly applied to the lower surface of the first portion from outside. That is, basically, the first portion only contacts the silicon substrate 100. Therefore, it is possible to prevent a stress acting between the stress generating film 112 and silicon substrate 100 from being restricted by other external force. Thus, also in the light of this, it can be said that it is possible to apply a satisfactory strain to the channel region.

According to the present embodiment, it is possible to give a satisfactory strain to the channel region to thereby increase the channel mobility of the MIS transistor. As a result, a semiconductor device excellent in performance can be obtained.

Although a portion (third portion connecting the first and second portions) that has been formed in the hole 109 of the stress generating film 112 does not completely fill the hole 109 in the above embodiment, the hole 109 may be filled completely with the third portion.

In the above embodiment, whether a stress generated by the stress generating film 112 is a compressive stress or tensile stress is not referred to, in particular. In other words, whether the stress generating film 112 gives a compressive strain or tensile strain to the channel region is not referred to. The type of the strain to be applied to the channel region is determined depending on the conductivity type of the channel region. For example, if the conductivity type of the channel region is N-type (i.e., in the case of N-type MIS transistor), the stress generating film 112 is so formed as to give a tensile strain to the channel region; and if the conductivity type of the channel region is P-type (i.e., in the case of P-type MIS transistor), the stress generating film 112 is so formed as to give a compressive strain to the channel region. In the case where the stress generating film is formed of a silicon nitride film, film formation condition of the silicon nitride film is changed to thereby change the composition ratio (Si/N composition ratio) of the silicon nitride film. This allows a compressive strain or tensile strain to be applied to the channel region.

### SECOND EMBODIMENT

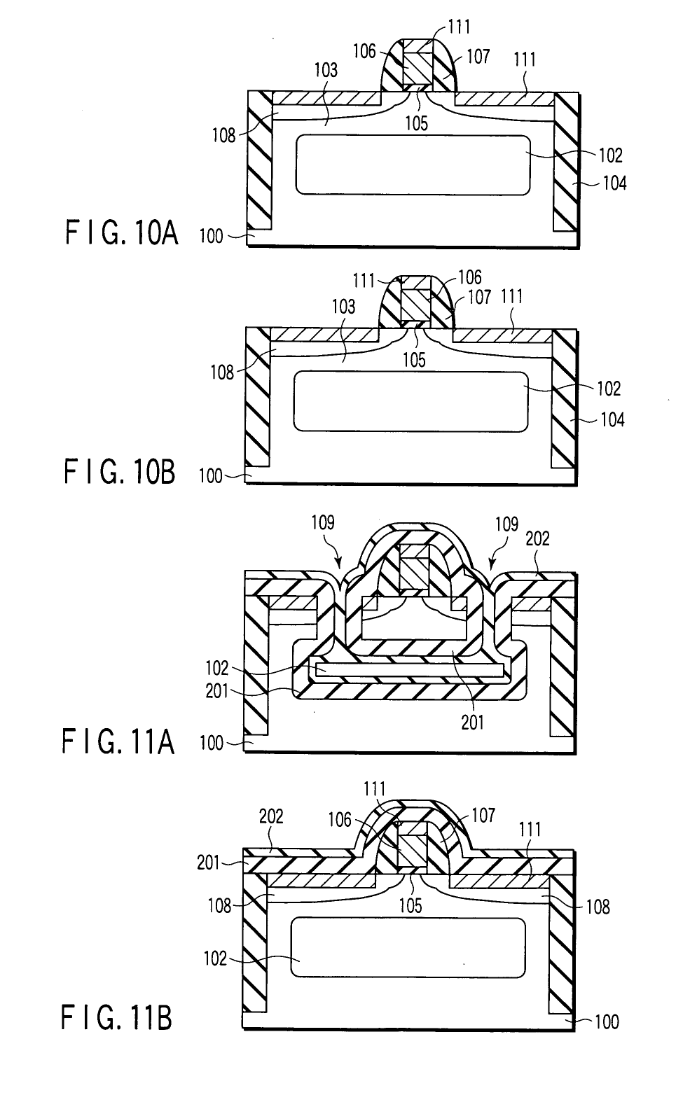

FIGS. 10A to 14A and FIGS. 10B to 14B are views schematically showing a manufacturing method of a semiconductor device according to a second embodiment of the present invention. In the present embodiment, both N-type MIS transistor and P-type MIS transistor are formed on the same substrate. FIGS. 10A to 14A show an N-type MIS transistor region and FIGS. 10B to 14B show a P-type MIS transistor region. The basic structure and manufacturing method in the second embodiment are similar to those in the first embodiment. Therefore, the same reference numerals as the first embodiment are given to the components corresponding to the first embodiment, and the description thereof is omitted here.

Firstly, the same processes as those shown in FIGS. 1A to 5A, FIGS. 1B to 5B, and FIGS. 4C to 5C of the first embodiment are performed. As a result, an N-type MIS transistor and P-type MIS transistor are formed in the N-type MIS transistor region and P-type MIS transistor region, respectively. In the first embodiment, the hole 109 is formed in the process shown in FIGS. 6A to 6C after the process of FIGS. 5A to 5C; while, in the present embodiment, the hole 109 is not formed after the process of FIGS. 5A to 5C but the same processes as those shown in FIGS. 7A to 7C and FIGS. 8A to 8C of the first embodiment are performed. As a result, a structure as shown in FIGS. 10A and 10B is obtained. That is, so called a salicide structure in which an Ni silicide film 111 has been formed on the gate electrode 106 and source/drain region 108 is obtained. Note that, in the present embodiment, not the silicon nitride film but the silicon oxide film is used as the gate side wall 107 so that the gate side wall 107 is not etched in the subsequent processes.

Next, as shown in FIGS. 11A and 11B, the hole 109 is formed only in the N-type MIS transistor region. Further, a silicon nitride film is formed as the stress generating film for generating a tensile stress by a low pressure CVD process. As a result, a silicon nitride film 201 is formed on the entire inner surface of the cavity 102 in the N-type MIS transistor region, as in the case of the first embodiment. Subsequently, a silicon oxide film is formed as an etching stopper film 202. Although the hole 109 is filled completely with the stress generating film 201 and etching stopper film 202 in the drawings, the hole 109 is not necessarily be filled completely therewith.

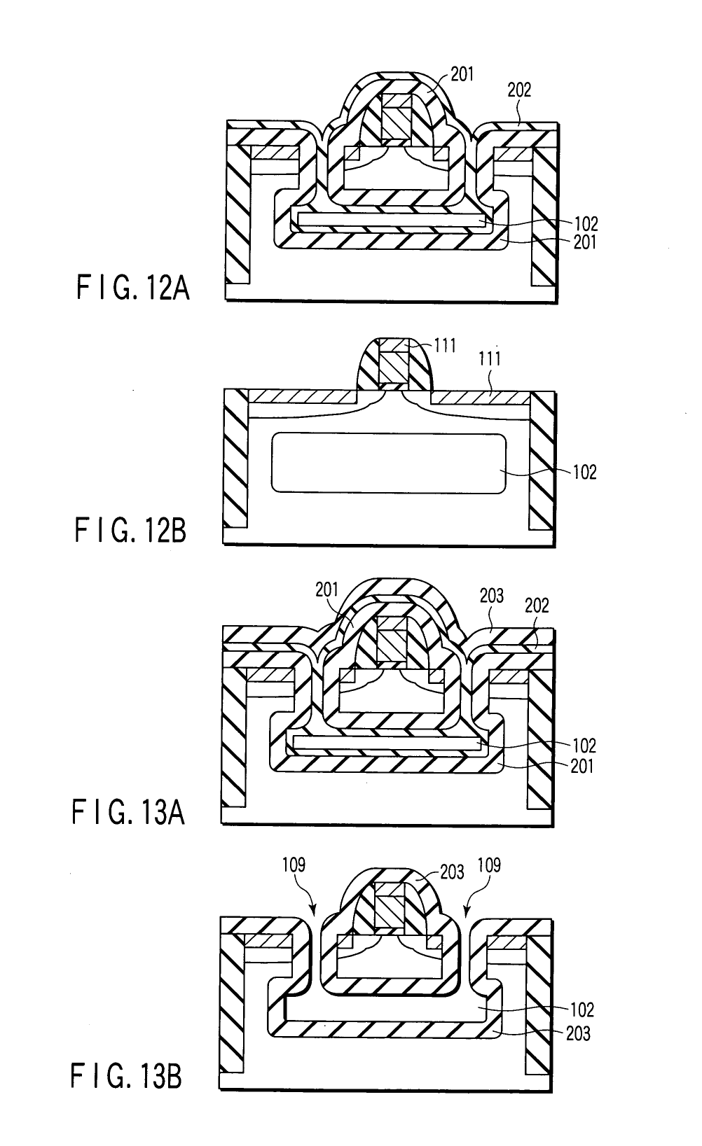

Next, as shown in FIGS. 12A and 12B, lithography and dry etching techniques are used to remove the etching stopper film 202 in the P-type MIS transistor region. Subsequently, hot phosphoric acid or the like is used to remove the stress generating film 201 in the P-type MIS transistor region. The dry etching technique may be used to remove the stress generating film 201.

Next, as shown in FIGS. 13A and 13B, the hole 109 is formed only in the P-type MIS transistor region. Further, a silicon nitride film is formed as a stress generating film 203 for generating a compressive stress by a low pressure CVD process. As a result, a silicon nitride film 203 is formed on the entire inner surface of the cavity 102 in the P-type MIS transistor region, as in the case of the first embodiment.

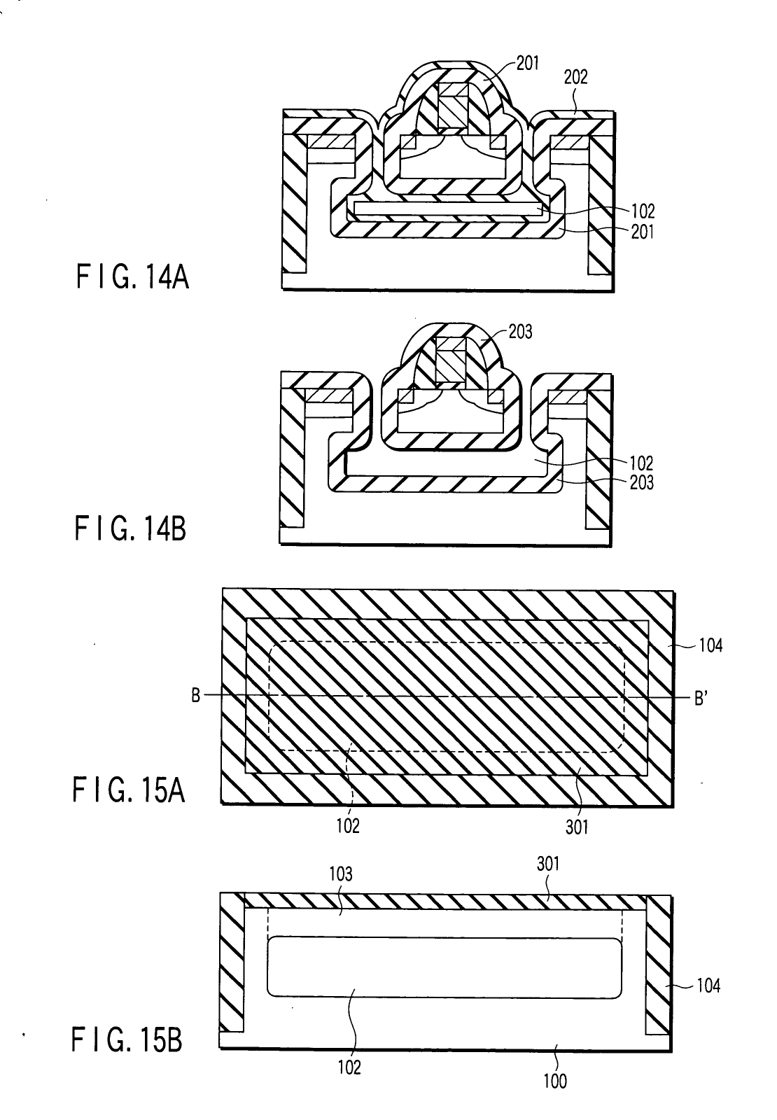

Next, as shown in FIGS. 14A and 14B, lithography and dry etching techniques are used to remove the stress generating film 203 in the N-type MIS transistor region. In the manner as described above, a structure in which the stress generating film 201 for generating a tensile stress has been formed is obtained in the N-type MIS transistor region; while a structure in which the stress generating film 203 for generating a compressive stress has been formed is obtained in the P-type MIS transistor region.

Although not shown in particular, formation processes of an interlayer insulating film, contacts connected respectively to the source region and drain region, and the like are performed subsequently.

As described above, in the present embodiment, the structure having the stress generating film 201 in the N-type MIS transistor region and structure having the stress generating film 203 in the P-type MIS transistor region are obtained as in the case of the first embodiment. Therefore, as is the case with the first embodiment, it is possible to apply a satisfactory strain to the channel region to thereby increase the channel mobility of the MIS transistor. As a result, a semiconductor device excellent in performance can be obtained.

Further, in the present embodiment, a structure in which the stress generating film 201 having a tensile stress has been formed is obtained in the N-type MIS transistor region and a structure in which the stress generating film 203 having a compressive stress has been formed is obtained in the P-type MIS transistor region. Therefore, it is possible to apply an adequate strain according to the conductivity type of the MIS transistor to the channel region. Thus, also in the light of this, it can be said that a semiconductor device excellent in performance can be obtained.

### THIRD EMBODIMENT

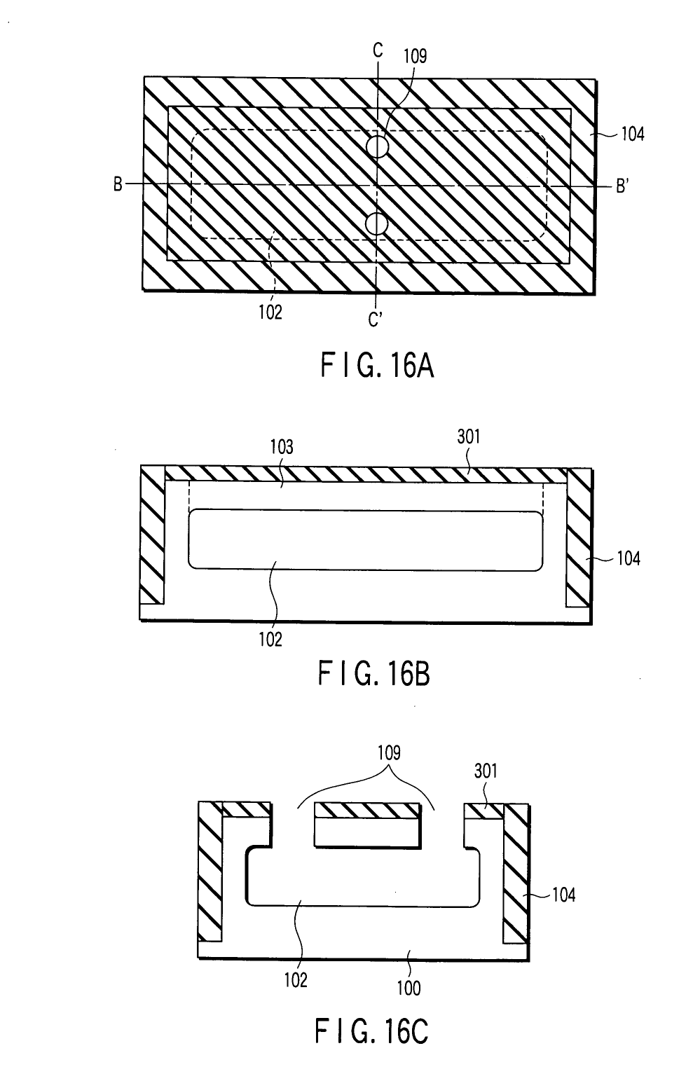

FIGS. 15A to 19A, FIGS. 15B to 19B, and FIGS. 16C to 19C are views schematically showing a manufacturing method of a semiconductor device according to a third embodiment of the present invention. Although the hole 109 which reaches the cavity 102 and stress generating film 112 are formed after formation of the MIS transistor in the first embodiment, the hole and stress generating film are formed before the formation of the MIS transistor in the present embodiment. FIGS. 15A to 19A are plan views, FIGS. 15B to 19B are cross-sectional views taken along B-B′ lines of FIGS. 15A to 19A, and FIGS. 16C to 19C are cross-sectional views taken along C-C′ lines of FIGS. 16A to 19A. The basic structure and manufacturing method in the third embodiment are similar to those in the first embodiment. Therefore, the same reference numerals as the first embodiment are given to the components corresponding to the first embodiment, and the description thereof is omitted.

Firstly, as shown in FIGS. 15A and 15B, the same processes as those shown in FIGS. 1A to 3A and FIGS. 1B to 3B of the first embodiment are performed. As a result, the cavity 102, SON region 103, and isolation region 104 are formed in the silicon substrate 100. Subsequently, a protective insulating film 301 formed of a silicon oxide film is formed on the surface of the silicon substrate 100 by a thermal oxidation process.

Next, as shown in FIGS. 16A, 16B, and 16C, the hole 109 which reaches the cavity 102 is formed in the SON region 103 of the silicon substrate 100. Although two holes 109 are formed in the drawings, the number of holes 109 to be formed may be one, or three or more.

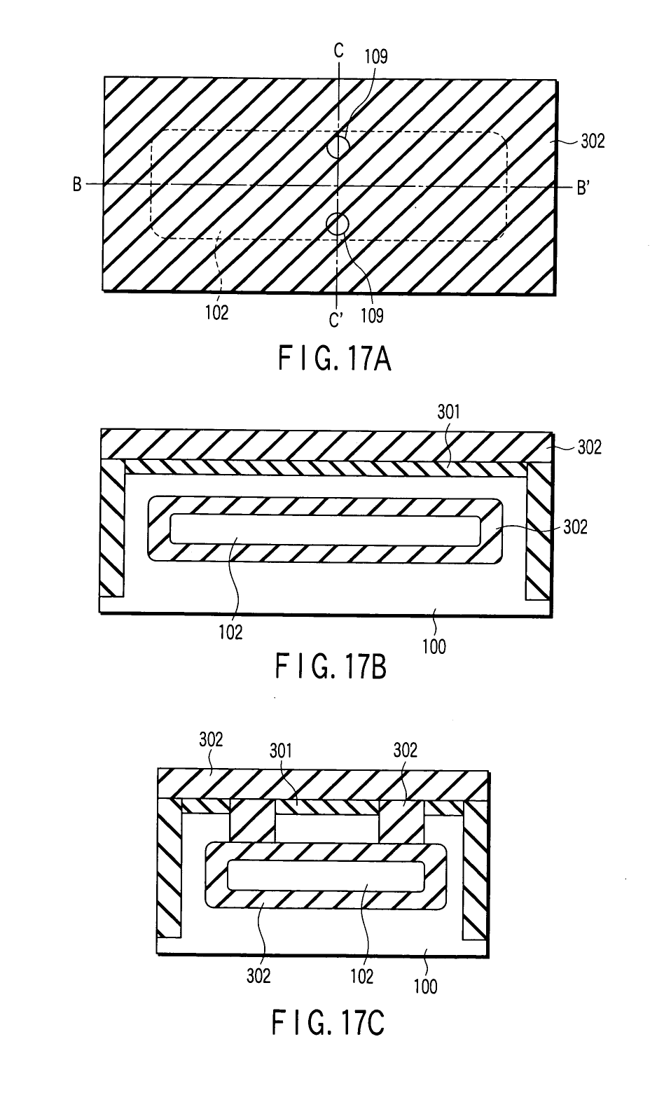

Next, as shown in FIGS. 17A, 17B, and 17C, a silicon nitride film is formed as a stress generating film 302 by a low pressure CVD process. The silicon nitride film 302 is formed on the surface of the silicon substrate 100 and on the entire inner surface of the cavity 102. The silicon nitride film 302 is so formed as to completely fill the hole 109. As has been described above, the stress generating film 302 having a tensile stress is formed in the N-type MIS transistor region; while the stress generating film 302 having a compressive stress is formed in the P-type MIS transistor region.

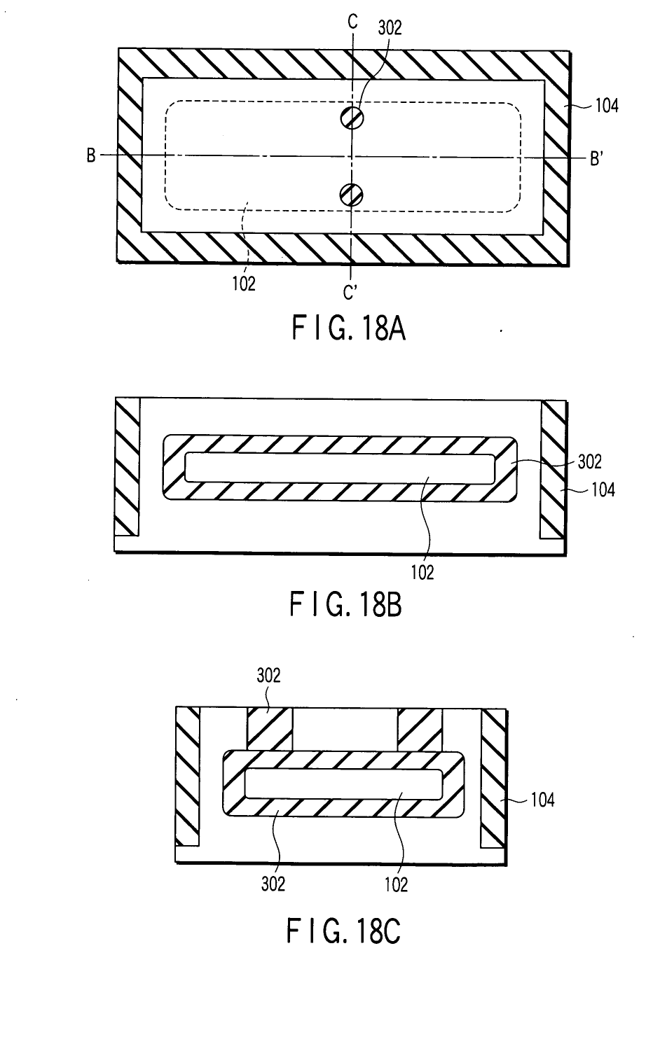

Next, as shown in FIGS. 18A, 18B, and 18C, wet etching is performed to remove the stress generating film 302 and protective insulating film 301 that have been formed on the surface of the silicon substrate 100. As a result, the stress generating film 302 remains in the cavity 102 and hole 109.

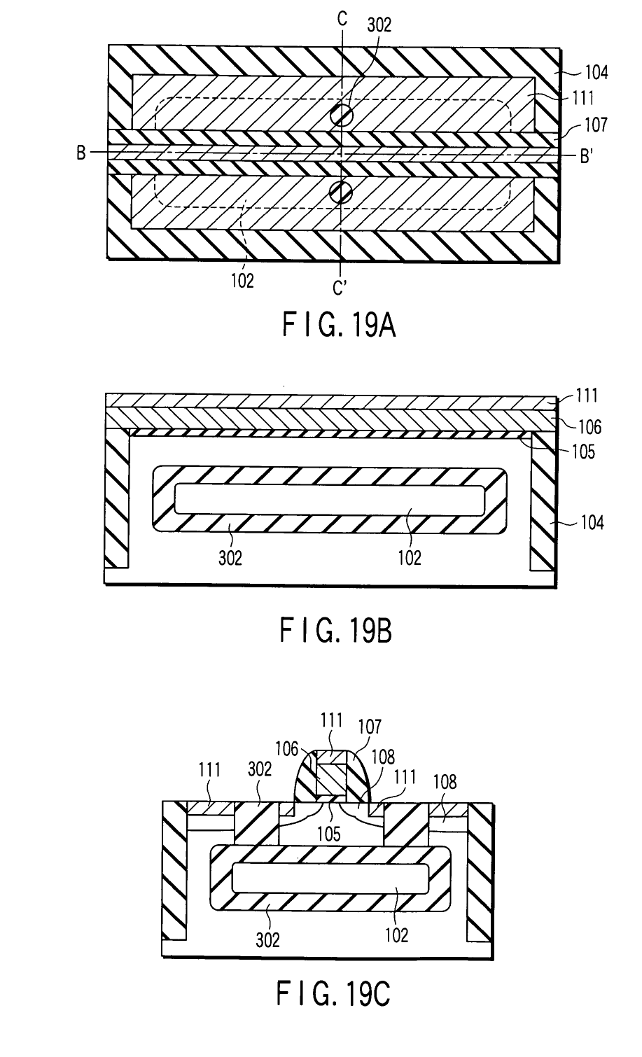

Next, as shown in FIGS. 19A, 19B, and 19C, the same processes as those shown in FIGS. 4A to 4C, FIGS. 5A to 5C, FIGS. 7A to 7C, and FIGS. 8A to 8C of the first embodiment are performed. As a result, the gate insulating film 105, gate electrode 106, gate side wall 107, source/drain region 108, and Ni silicide film 111 are formed. That is, the MIS transistor is obtained. Note that, after formation of the MIS transistor, another stress generating film (silicon nitride film) may be so formed as to cover the surface of the substrate on which the MIS transistor has been formed.

Although not shown in particular, formation processes of an interlayer insulating film, contacts connected respectively to the source region and drain region, and the like are performed subsequently.

As described above, also in the present embodiment, the cavity 102 is formed under the first portion (portion that has been formed on the upper surface of the cavity 102) of the stress generating film 302, as in the case of the first embodiment. This prevents a stress from being directly applied to the lower surface of the first portion from outside. That is, the first portion basically contacts only the silicon substrate 100. Therefore, it is possible to prevent a stress acting between the stress generating film 302 and silicon substrate 100 from being restricted by other external force. Thus, as is the case with the first embodiment, it is possible to give a satisfactory strain to the channel region to thereby increase the channel mobility of the MIS transistor. As a result, a semiconductor device excellent in performance can be obtained.

Although a silicon nitride film (or more generally speaking, a film containing silicon and nitrogen) is used as the stress generating film in the above first to third embodiments, other films may be used as the stress generating film. For example, an aluminum oxide film (alumina film) may be used as the stress generating film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate which has a cavity and has a source region, a drain region, and a channel region above the cavity;
a gate electrode which is formed on the channel region with a gate insulating film interposed between the gate electrode and the channel region; and
a stress generating film which has a first portion formed on the upper surface of the cavity and which gives a strain to the channel region.

2. The semiconductor device according to claim 1, wherein
the stress generating film further has a second portion that covers the source region and the drain region.

3. The semiconductor device according to claim 2, wherein
the semiconductor substrate further has a hole which reaches the cavity.

4. The semiconductor device according to claim 3, wherein
the stress generating film further has a third portion formed in the hole.

5. The semiconductor device according to claim 4, wherein
the third portion connects the first and second portions.

6. The semiconductor device according to claim 3, wherein
the semiconductor substrate has a plurality of the holes.

7. The semiconductor device according to claim 1, wherein
the stress generating film has a portion formed on an entire inner surface of the cavity, the portion including the first portion.

8. The semiconductor device according to claim 1, wherein
the semiconductor substrate further has a hole which reaches the cavity.

9. The semiconductor device according to claim 8, wherein
the stress generating film further has a third portion formed in the hole.

10. The semiconductor device according to claim 8, wherein
the semiconductor substrate has a plurality of the holes.

11. The semiconductor device according to claim 1, wherein
an N-type channel is to be induced in the channel region, and
the stress generating film gives a tensile strain to the channel region.

12. The semiconductor device according to claim 1, wherein
a P-type channel is to be induced in the channel region, and
the stress generating film gives a compressive strain to the channel region.

13. The semiconductor device according to claim 1, wherein
the stress generating film is formed of a film containing silicon and nitrogen or an aluminum oxide film.

14. The semiconductor device according to claim 1, wherein
the stress generating film is formed of a CVD film.

15. The semiconductor device according to claim 1, wherein
the semiconductor substrate is a silicon substrate.
